(19) United States
(12) Patent Application Publication
(10) Pub. No.: US 2025/0098154 A1
(43) Pub. Date: Mar. 20, 2025

(54) SEMICONDUCTOR DEVICE AND METHOD OF MANUFACTURING THE SAME

(71) Applicant: Samsung Electronics Co., Ltd., Suwon-si (KR)

(72) Inventors: Sanghyun SUNG, Suwon-si (KR); Seokhan PARK, Suwon-si (KR); Gyuhwan OH, Suwon-si (KR); Bowon YOO, Suwon-si (KR); Jinwoo HAN, Suwon-si (KR)

(73) Assignee: Samsung Electronics Co., Ltd., Suwon-si (KR)

(21) Appl. No.: 18/825,176

(22) Filed: Sep. 5, 2024

(30) Foreign Application Priority Data
Sep. 20, 2023 (KR) 10-2023-0125855

(51) Int. Cl. H10B 12/00

(52) U.S. Cl. CPC H10B 12/482; H10B 12/02; H10B 12/315

(57) ABSTRACT

A semiconductor device includes bit lines, which are apart from each other in a first direction and extend in a second direction that crosses the first direction, above a top surface of a substrate, comb-type insulating patterns arranged among the bit lines in the first direction and apart from each other in the second direction, line insulating layers apart from each other in the first direction, extending in the second direction, and covering the bit lines and portions of the comb-type insulating patterns from below, and a conductive line shield layer covering the line insulating layers and the other portions of the comb-type insulating patterns from below.

### CROSS-REFERENCE TO RELATED APPLICATION

This application is based on and claims priority under 35 U.S.C. § 119 to Korean Patent Application No. 10-2023-0125855, filed on Sep. 20, 2023, in the Korean Intellectual Property Office, the disclosure of which is incorporated by reference herein in its entirety.

### BACKGROUND

Various non-limiting example embodiments relate, in general, to a semiconductor device and/or a method of manufacturing the same, and more particularly, to a semiconductor device including a vertical channel transistor and/or a method of manufacturing the same.

To meet or partially meet high performance and economic feasibility, it is necessary or desirable to increase the integration density of semiconductor devices. In particular, the integration density of memory devices is an important factor in determining the economic feasibility of products. The integration density of two-dimensional (2D) memory devices is mainly determined by the area of a memory cell unit and is thus greatly influenced by the level of a micropatterning technique. However, because expensive equipment is needed or used to form micropatterns and the area of a chip die is limited, the integration density of 2D memory devices is still limited, although it is increasing.

### SUMMARY

Various non-limiting example embodiments provide a semiconductor device including a vertical channel transistor with reduced process difficulty and/or improved electrical characteristics, and/or a method of manufacturing the semiconductor device.

Inventive concepts are not limited to what is mentioned above and will be clearly understood by those of ordinary skill in the art from the descriptions below.

According to some example embodiments, there is provided a semiconductor device including a substrate, bit lines above a top surface of the substrate, the bit lines apart from each other in a first direction and extending in a second direction crossing the first direction, comb-type insulating patterns arranged among the bit lines in the first direction and apart from each other in the second direction, line insulating layers apart from each other in the first direction, extending in the second direction, and covering the bit lines and portions of the comb-type insulating patterns from below, a line shield layer covering the line insulating layers and remaining portions of the comb-type insulating patterns from below, the line shield layer being conductive, a pair of active patterns on each of the bit lines, a back-gate electrode between the pair of active patterns and extending in the first direction, and a pair of word lines outside the pair of active patterns and extending in the first direction.

Alternatively or additionally according to various example embodiments, there is provided a semiconductor device including a substrate, bit lines above a top surface of the substrate, the bit lines being apart from each other in a first direction and extending in a second direction crossing the first direction, island insulating patterns zigzagging among the bit lines in the first direction and the second direction, line insulating layers apart from each other in the first direction, extending in the second direction, and covering the bit lines and portions of the island insulating patterns from below, a line shield layer covering the line insulating layers and remaining portions of the island insulating patterns from below, the line shield layer being conductive, a pair of active patterns on each of the bit lines, a back-gate electrode between the pair of active patterns and extending in the first direction, and a pair of word lines arranged outside the pair of active patterns and extending in the first direction.

Alternatively or additionally according to various example embodiments, there is provided a method of manufacturing a semiconductor device. The method includes preparing a first substrate including an active layer, forming a back-gate electrode extending in a first direction in the active layer, forming a pair of active patterns respectively at opposite sides of the back-gate electrode by patterning the active layer, forming a pair of word lines outside the pair of active patterns, forming bit lines extending across the pair of word lines in a second direction crossing the first direction, the bit lines being in contact with first surfaces of the pair of active patterns, forming comb-type insulating patterns in the first direction among the bit lines, the comb-type insulating patterns being apart from each other in the second direction, forming line insulating layers covering the bit lines and portions of the comb-type insulating patterns, the line insulating layers being apart from each other in the first direction and extending in the second direction, forming a line shield layer covering the line insulating layers and the other portions of the comb-type insulating patterns, forming a base insulating layer covering the line shield layer, bonding a second substrate to the base insulating layer, turning the second substrate upside down, and removing the first substrate.

### BRIEF DESCRIPTION OF THE DRAWINGS

Embodiments will be more clearly understood from the following detailed description taken in conjunction with the accompanying drawings in which:

FIG. 1 illustrates a layout of a semiconductor device according to various example embodiments;

FIG. 2 is a cross-sectional view taken along line A1-A1′ in FIG. 1;

FIG. 3 is a cross-sectional view taken along line A2-A2′ in FIG. 1;

FIG. 4 is a cross-sectional view taken along line A3-A3′ in FIG. 1;

FIG. 5 is a perspective view illustrating the surroundings of a bit line of the semiconductor device of FIG. 1;

FIG. 6 illustrates a layout of a semiconductor device according to some example embodiments;

FIG. 7 is a cross-sectional view taken along line A1-A1′ in FIG. 6;

FIG. 8 is a cross-sectional view taken along line A2-A2′ in FIG. 6;

FIG. 9 is a cross-sectional view taken along line A3-A3′ in FIG. 6;

FIG. 10 is a perspective view illustrating the surroundings of a bit line of the semiconductor device of FIG. 6;

FIG. 11 is a flowchart of a method of manufacturing a semiconductor device, according to various example embodiments;

FIGS. 12A to 18C are diagrams illustrating the sequential stages in a method of manufacturing a semiconductor device, according to various example embodiments;

FIGS. 19A to 20C are diagrams illustrating the sequential stages in a method of manufacturing a semiconductor device, according to some example embodiments; and

FIG. 21 is a block diagram of a system including a semiconductor device, according to various example embodiments.

### DETAILED DESCRIPTION OF SOME EXAMPLE EMBODIMENTS

Hereinafter, various example embodiments are described in detail with reference to the accompanying drawings.

Herein, the terms “top/bottom”, “upper/lower”, “above/below”, etc. are used based on the directions shown in the accompanying drawings. Accordingly, even the same surface may be referred to as a top surface or a lower surface depending on the direction shown in the drawings.

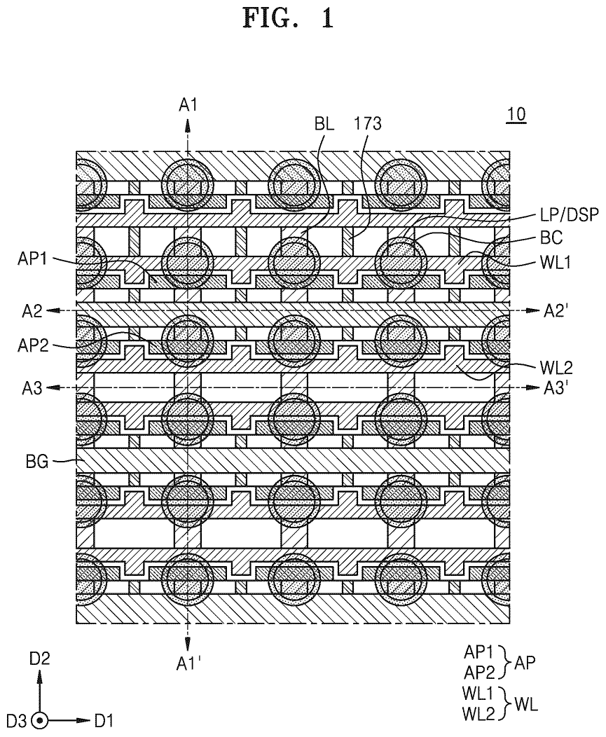

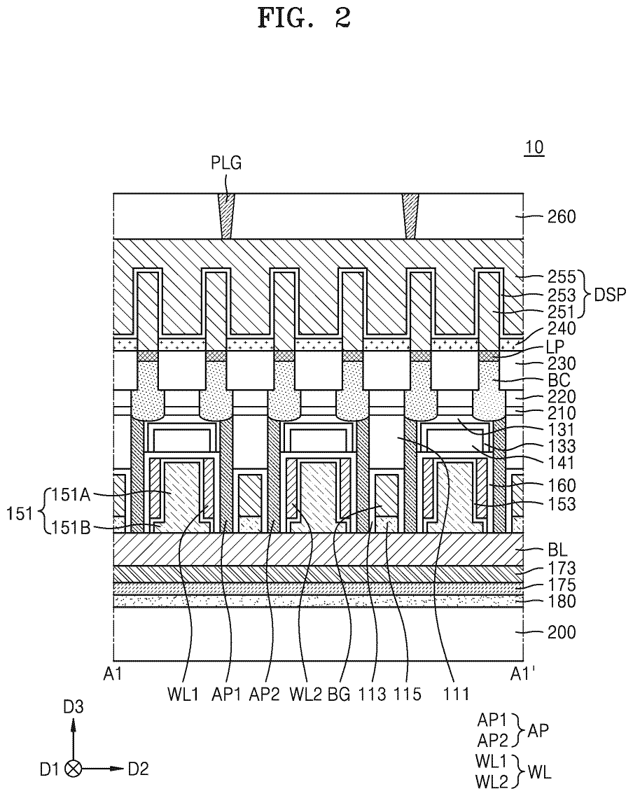

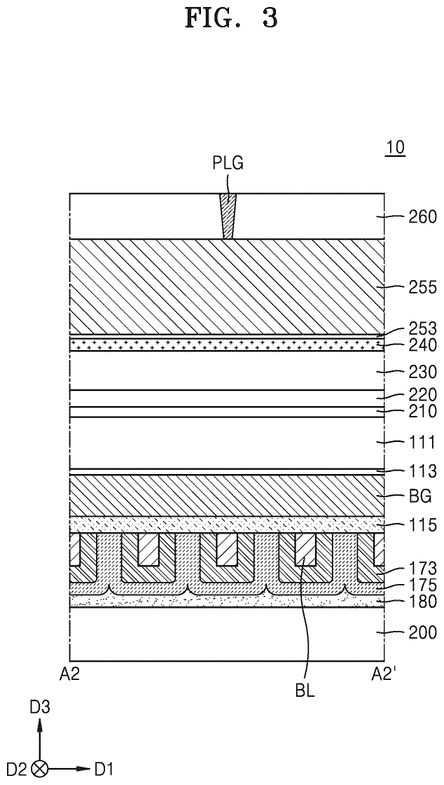

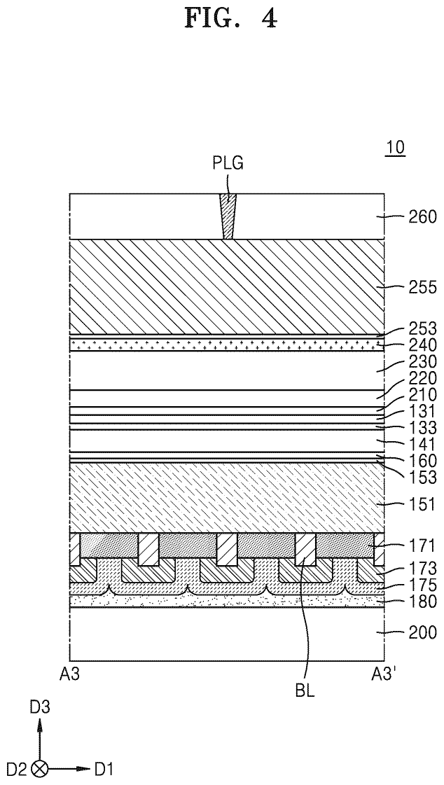

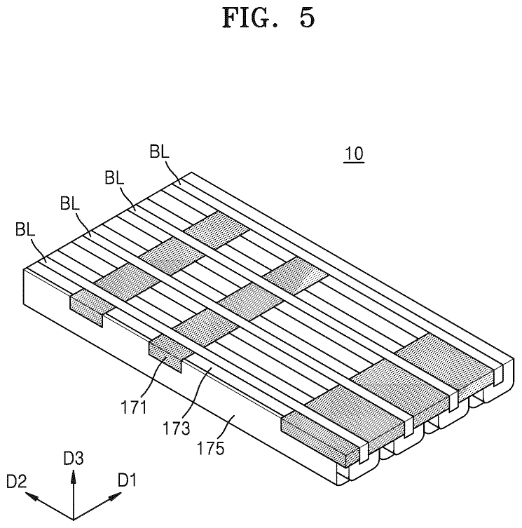

FIG. 1 illustrates a layout of a semiconductor device 10 according to various example embodiments. FIG. 2 is a cross-sectional view taken along line A1-A1′ in FIG. 1. FIG. 3 is a cross-sectional view taken along line A2-A2′ in FIG. 1. FIG. 4 is a cross-sectional view taken along line A3-A3′ in FIG. 1. FIG. 5 is a perspective view illustrating the surroundings of a bit line of the semiconductor device 10 of FIG. 1.

Referring to FIGS. 1 to 5, the semiconductor device 10 may include memory cells including a vertical channel transistor (VCT).

A substrate 200 may include a material (e.g., silicon and/or germanium) having semiconductor properties, an insulating material (e.g., glass and/or quartz), or a semiconductor or conductor covered with an insulating material. In some example embodiments, the substrate 200 may be doped, e.g., may be lightly doped; example embodiments are not limited thereto.

Column lines or bit lines BL may be apart from each other in a first direction D1 on the substrate 200. The bit lines BL may be apart from each other in the first direction D1 and may extend in a second direction D2 that crosses the first direction D1.

The bit lines BL may include conductive metal nitride (e.g., titanium nitride and/or tantalum nitride) and/or metal (e.g., one or more of tungsten, titanium, or tantalum). Alternatively, the bit lines BL may include metal silicide, such as one of, or more than one of, titanium silicide, cobalt silicide, or nickel silicide.

Active patterns AP may be alternately arranged in the second direction D2 on each of the bit lines BL. The active patterns AP may be apart from each other in the first direction D1 at regular intervals. For example, the active patterns AP may be arranged in two dimensions in the first direction D1 and the second direction D2, which cross each other.

Each of the active patterns AP may have a length in the first direction D1, a width in the second direction D2, and a height in a third direction D3, the third direction D3 perpendicular to the substrate 200 (e.g., a surface of the substrate 200). Each of the active patterns AP may have a uniform width. Each of the active patterns AP may have a top surface and a bottom surface, which face each other in the third direction D3. For example, the bottom surface of each of the active patterns AP may be in contact with a bit line BL.

Each of the active patterns AP may include a source region (not shown) adjacent to the bit line BL, a drain region (not shown) adjacent to a contact pattern BC, and a channel region (not shown) between the source region and the drain region. The active patterns AP may have impurities, such as one or more of boron (B), arsenic (As), or phosphorus (P), included therein. During the operation of (e.g., during electrical operation of) the semiconductor device 10, the channel regions of the active patterns AP may be controlled by word lines WL and back-gate electrodes BG. Because the active patterns AP include a monocrystalline semiconductor material, leakage current characteristics may be improved in the operation of the semiconductor device 10. For example, the active patterns AP may include monocrystalline silicon (Si), and may be doped with impurities.

The back-gate electrodes BG may be on the bit lines BL and apart from each other in the second direction D2 at regular intervals. Each of the back-gate electrodes BG may extend across the bit lines BL in the first direction D1.

Each of the back-gate electrodes BG may be between active patterns AP adjacent to each other in the second direction D2. In some example embodiments, a first active pattern AP1 may be at one side of each of the back-gate electrodes BG and a second active pattern AP2 may be at an opposite side thereof. The back-gate electrodes BG may be lower than or below the active patterns AP in the vertical direction.

For example, the back-gate electrodes BG may include one or more of doped polysilicon, conductive metal nitride (e.g., titanium nitride or tantalum nitride), metal (e.g., tungsten, titanium, or tantalum), conductive metal silicide, conductive metal oxide, or a combination thereof.

During the operation of (or electrical operation of) the semiconductor device 10, a negative voltage may be applied to the back-gate electrodes BG, and the back-gate electrodes BG may increase or increase the absolute value of the threshold voltage of a VCT. In some example embodiments, leakage current characteristics may be prevented from or reduced in likelihood of decreasing because a threshold voltage decreases with the miniaturization of a VCT.

A first insulating pattern 111 may be between active patterns AP adjacent to each other in the second direction D2. The first insulating pattern 111 may extend in the first direction D1 to be parallel with the back-gate electrodes BG. The distance between a second surface of each of the active patterns AP and one of the back-gate electrodes BG may vary with the thickness of the first insulating pattern 111. In some example embodiments, the first insulating pattern 111 may include one or more of a silicon oxide film, a silicon oxynitride film, or a silicon nitride film.

A back-gate insulating film 113 may be between a back-gate electrode BG and active patterns AP and between the back-gate electrode BG and the first insulating pattern 111. The back-gate insulating film 113 may include vertical portions, which respectively cover opposite side surfaces of the back-gate electrode BG, and a horizontal portion, which connects the vertical portions to each other. The horizontal portion of the back-gate insulating film 113 may be closer to the contact pattern BC than to a bit line BL and may cover the top surface of the back-gate electrode BG.

For example, the back-gate insulating film 113 may include a silicon oxide film, a silicon oxynitride film, a high-k dielectric film having a higher dielectric constant than the silicon oxide film, or a combination thereof.

A back-gate capping pattern 115 may be between the bit lines BL and the back-gate electrode BG. The back-gate capping pattern 115 may include an insulating material, and the bottom surface of the back-gate capping pattern 115 may be in contact with the bit lines BL. The back-gate capping pattern 115 may be between the vertical portions of the back-gate insulating film 113. The thickness of the back-gate capping pattern 115 between the bit lines BL may be different from (e.g., thinner than or thicker than) the thickness of the back-gate capping pattern 115 on the bit lines BL.

The word lines WL may extend in the first direction D1 on the bit lines BL and may be alternately arranged in the second direction D2.

A first word line WL1 of the word lines WL may be at one side of the first active pattern AP1 and a second word line WL2 may be at the opposite side of the second active pattern AP2. For example, a portion of the first word line WL1 may be between first active patterns AP1 adjacent to each other in the first direction D1 and a portion of the second word line WL2 may be between second active patterns AP2 adjacent to each other in the first direction D1.

The word lines WL may be vertically apart from the bit lines BL and contact patterns BC. For example, when viewed in the vertical direction, the word lines WL may be between the bit lines BL and the contact pattern BC.

For example, the word lines WL may include doped polysilicon, metal, conductive metal nitride, conductive metal silicide, conductive metal oxide, or a combination thereof.

Word lines WL adjacent to each other may respectively have side walls facing each other. The word lines WL may be lower than the active patterns AP in the vertical direction. The height of the word lines WL may be greater than or equal to the height of the back-gate electrodes BG in the third direction D3.

Gate insulating films 160 may be between the word lines WL and the active patterns AP. The gate insulating films 160 may extend in the first direction D1 in parallel with the word lines WL.

Each of the gate insulating films 160 may include a silicon oxide film, a silicon oxynitride film, a high-k dielectric film having a higher dielectric constant than the silicon oxide film, or a combination thereof. The high-k dielectric film may include metal oxide or metal oxynitride. For example, the high-k dielectric film usable for each gate insulating film 160 may include, but not limited to, HfO₂, HfSiO, HfSiON, HfTaO, HTIO, HfZrO, ZrO₂, Al₂O₃, or a combination thereof.

The gate insulating film 160 may cover a side surface of a first active pattern AP1 and an opposite side surface of a second active pattern AP2. The gate insulating film 160 may have a substantially uniform thickness, and in some example embodiments may be conformal. A second insulating pattern 141 may be between the gate insulating film 160 and the contact patterns BC. For example, the second insulating pattern 141 may include silicon oxide. A first etch stop film 131 and a second etch stop film 133 may be between active patterns AP and the second insulating pattern 141.

Word lines WL may be separated from each other by a third insulating pattern 151 on the gate insulating film 160. The third insulating pattern 151 may extend in the first direction D1 between the word lines WL. A first capping film 153 may be between the third insulating pattern 151 and the word lines WL. The first capping film 153 may have a substantially uniform thickness, and in some example embodiments may be conformal. The third insulating pattern 151 may include a third vertical pattern 151A and a third horizontal pattern 151B.

The contact patterns BC may pass through a third etch stop film 210 and an interlayer insulating film 220 and may be respectively connected to the active patterns AP. For example, the contact patterns BC may be respectively connected to the drain regions of the active patterns AP. The contact patterns BC may have a lower width that is greater than an upper width. Adjacent contact patterns BC may be separated from each other by an isolation insulating pattern 230. According to a plan view, each of the contact patterns BC may have various shapes, such as one or more of a circle, an oval, a rectangle, a square, a diamond, and a hexagon.

Landing pads LP may be respectively on the contact patterns BC. According to a plan view, each of the landing pads LP may have various shapes, such as a circle, an oval, a rectangle, a square, a diamond, and a hexagon.

The isolation insulating pattern 230 may be between two adjacent landing pads LP. According to a plan view, the landing pads LP may be arranged in a matrix in the first direction D1 and the second direction D2. The top surfaces of the landing pads LP may be coplanar with the top surface of the isolation insulating pattern 230. A fourth etch stop film 240 may be on the isolation insulating pattern 230.

The landing pads LP may include, but not limited to, doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrO, RuO, or a combination thereof.

Data storage patterns DSP may be respectively on the landing pads LP. The data storage patterns DSP may be respectively and electrically connected to the active patterns AP. The data storage patterns DSP may be arranged in a matrix in the first direction D1 and the second direction D2. The data storage patterns DSP may entirely or partially overlap the landing pads LP, respectively. Each of the data storage patterns DSP may be in contact with the entirety or a portion of the top surface of one of the landing pads LP.

In some example embodiments, the data storage patterns DSP may be or may include or correspond to a capacitor and include a capacitor dielectric film 253 between storage electrodes 251 and a plate electrode 255. In this case, each of the storage electrodes 251 may be in direct contact with a landing pad LP. According to a plan view, each of the storage electrodes 251 may have various shapes, such as one or more of a circle, an oval, a rectangle, a square, a diamond, and a hexagon.

Alternatively or additionally, the data storage patterns DSP may be or include or correspond to correspond to a variable resistance pattern that may switch between two resistance states in response to an electrical pulse applied to a memory element. For example, the data storage patterns DSP may include, but not limited to, one or more of a phase-change material, a perovskite compound, transition metal oxide, a magnetic material, a ferromagnetic material, or an antiferromagnetic material, of which the crystal state changes according to the amount of current.

An upper insulating film 260 may be on the data storage patterns DSP. Cell contact plugs PLG may pass through the upper insulating film 260 and may be connected to the plate electrode 255.

Although not shown, other devices such as resistors and/or diodes and/or peripheral circuit transistors may be arranged in a peripheral circuit region of the substrate 200. In the peripheral circuit region, an active layer may include the same monocrystalline semiconductor material as the active patterns AP. The active layer may have a bottom surface in contact with the substrate 200 and a top surface facing the bottom surface. The bottom surface of the active layer may be substantially coplanar with the bottom surfaces of the active patterns AP. Peripheral circuit transistors may be arranged on the top surface of the active layer. For example, a peripheral gate structure may be arranged on the top surface of the active layer. In some example embodiments, the peripheral transistors may be or may include planar transistors and/or three-dimensional transistors.

In the semiconductor device 10 according to various example embodiments, a line shield layer 175 may be between bit lines BL and below the bit lines BL. The line shield layer 175 may reduce or improve upon coupling noise (bitline-bitline capacitance) between bit lines BL adjacent to each other. For example, the line shield layer 175 may correspond to a shielding structure including a conductive material. To insulate the line shield layer 175 that is conductive from the bit lines BL that are conductive, comb-type insulating patterns 171 and line insulating layers 173 may be arranged to fill between the line shield layer 175 and the bit lines BL.

The comb-type insulating patterns 171 may be arranged among the bit lines BL in the first direction D1 and apart from each other in the second direction D2. The comb-type insulating patterns 171 may be in contact with respective facing sidewalls of bit lines BL adjacent to each other and may extend in the first direction D1 along an imaginary line. In some example embodiments, the comb-type insulating patterns 171 may be arranged in mirror symmetry with respect to the bit lines BL. Each of the comb-type insulating patterns 171 may have a cuboid shape but is not limited thereto. For example, the comb-type insulating patterns 171 may include, but not limited to, one or more of a silicon oxide film, a silicon oxynitride film, or a silicon nitride film.

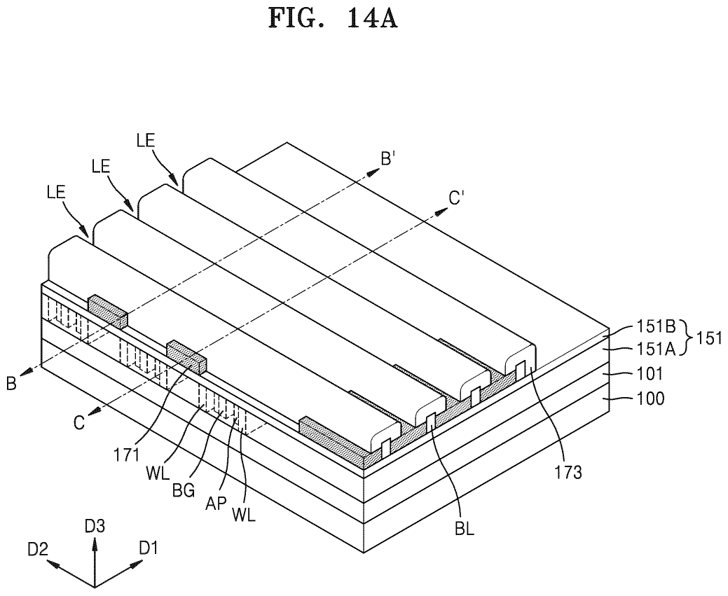

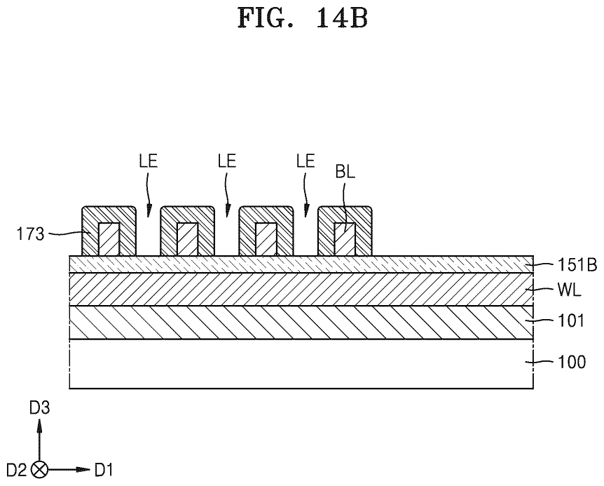

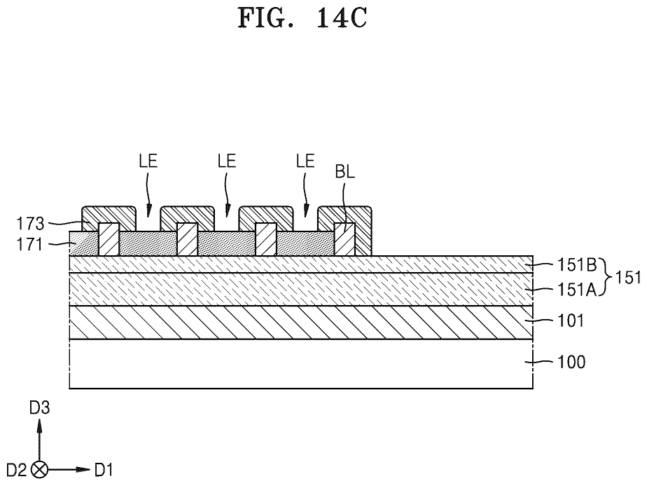

The line insulating layers 173 may be apart from each other in the first direction D1 and may extend in the second direction D2 and cover portions of the comb-type insulating patterns 171 and the bit lines BL from below. The line insulating layers 173 may be respectively in contact with respective facing sidewalls of bit lines BL adjacent to each other and apart from each other in the first direction D1. In some example embodiments, a long space LE (in FIG. 14A) extending in the second direction D2 may be between respective facing sidewalls of line insulating layers 173 adjacent to each other. The long space LE may be accurately identified in a method of manufacturing the semiconductor device 10, which is described below. For example, the line insulating layers 173 may include, but not limited to, a silicon oxide film, a silicon oxynitride film, or a silicon nitride film.

The line shield layer 175 may cover the other remaining portions of the comb-type insulating patterns 171 and the line insulating layers 173 from below. The line shield layer 175 may fill the long space LE (in FIG. 14A) between adjacent line insulating layers 173. In some example embodiments, the line shield layer 175 may include a metal material, such as one or more of tungsten (W), titanium (Ti), nickel (Ni), or cobalt (Co). In some example embodiments, the line shield layer 175 may include a conductive material, such as graphene, which includes carbon (C).

In the semiconductor device 10 of various example embodiments, a comb-type insulating pattern 171 may be in a portion of the gap between respective facing sidewalls of adjacent bit lines BL, and line insulating layers 173 and the line shield layer 175 may be in the other portion of the gap between the respective facing sidewalls of the adjacent bit lines BL. For example, the line shield layer 175 may be in the long space LE (in FIG. 14A) and may include a vertical portion, which faces sidewalls of the bit lines BL, and a horizontal portion, which is on the line insulating layers 173 and faces the bottom surface of the bit lines BL. Here, the vertical portion and the horizontal portion of the line shield layer 175 may form one body.

In some example embodiments, based on the top surface of the substrate 200, the topmost surfaces of the bit lines BL, the topmost surface of the comb-type insulating patterns 171, the topmost surfaces of the line insulating layers 173, and the topmost surface of the line shield layer 175 may be substantially coplanar with one another. Based on the top surface of the substrate 200, the bottommost surfaces of the bit lines BL may be at a lower level than the bottommost surfaces of the comb-type insulating patterns 171 and the bottommost surfaces of the line insulating layers 173 may be at a lower level than the bottommost surfaces of the bit lines BL. Based on the top surface of the substrate 200, the bottommost surface of the line shield layer 175 may be at a lower level than the bottommost surfaces of the line insulating layers 173.

A base insulating layer 180 may be between the substrate 200 and the line shield layer 175. Accordingly, the line shield layer 175 may be surrounded by the base insulating layer 180, the line insulating layers 173, and the comb-type insulating patterns 171.

Generally, the line shield layer 175 is arranged to reduce coupling noise between the bit lines BL, but both the bit lines BL and the line shield layer 175 include a conductive material, and accordingly, capacitance may increase between the bit lines BL and the line shield layer 175. The capacitance between the bit lines BL may be decreased by partially removing the line shield layer 175 by using an embossing method. Here, the embossing method may refer to an etching method in which the entirety of the line shield layer 175 is formed first and a portion of the line shield layer 175 is removed later. However, as the design rules of semiconductor devices gradually decrease, a very difficult process technique is required to remove only the line shield layer 175 in a desired etching area by using a dry etch without tolerance when the embossing method is used.

The semiconductor device 10 of inventive concepts may efficiently reduce process difficulty by using an engraving method allowing the line shield layer 175 to be formed in a desired region by forming first the comb-type insulating patterns 171 in a portion in which the line shield layer 175 is not to be formed. Here, the engraving method may refer to a damascene process in which a space having a desired shape is formed first and is filled with a material that is different from a material of a region around the space. Accordingly, even when the design rules of semiconductor devices decrease, the line shield layer 175 may be formed to have a desired shape without using an etching process.

Eventually, the semiconductor device 10 of inventive concepts may enable the decrease of process difficulty and the improvement of electrical characteristics by forming the line shield layer 175, which significantly reduces coupling noise between the bit lines BL and efficiently suppresses the increase of capacitance between the bit lines BL, using an engraving method.

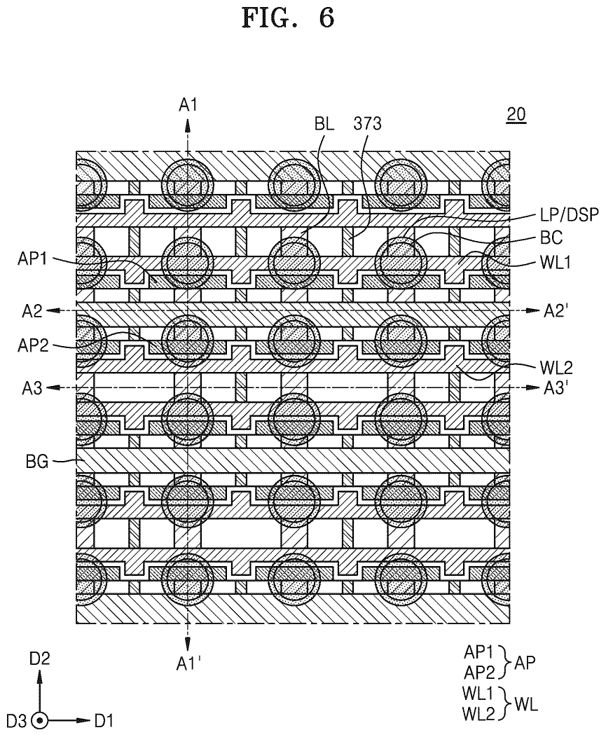

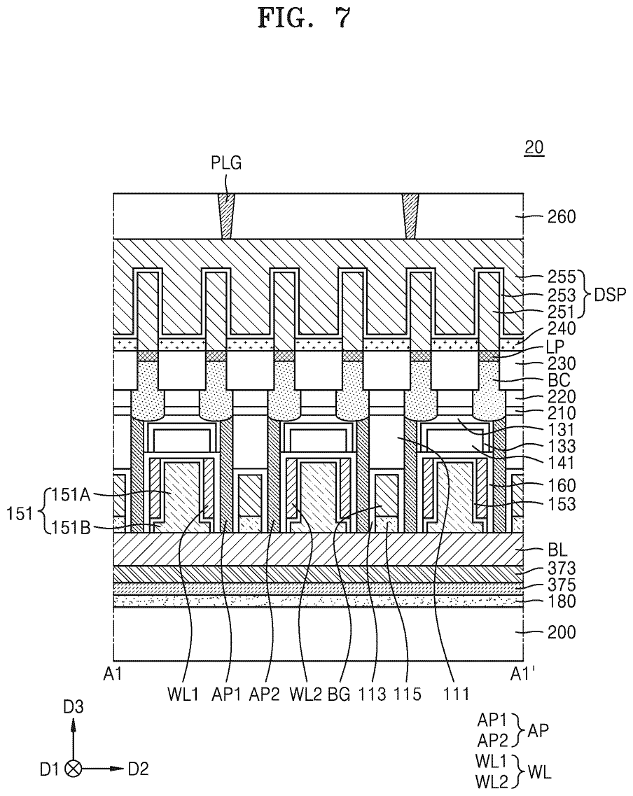

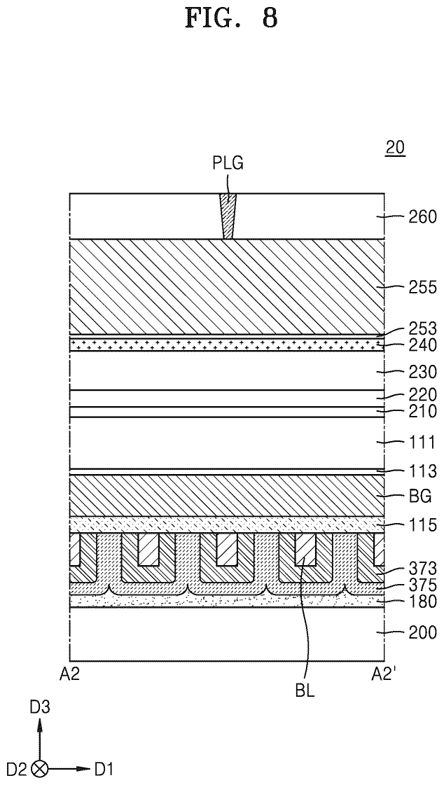

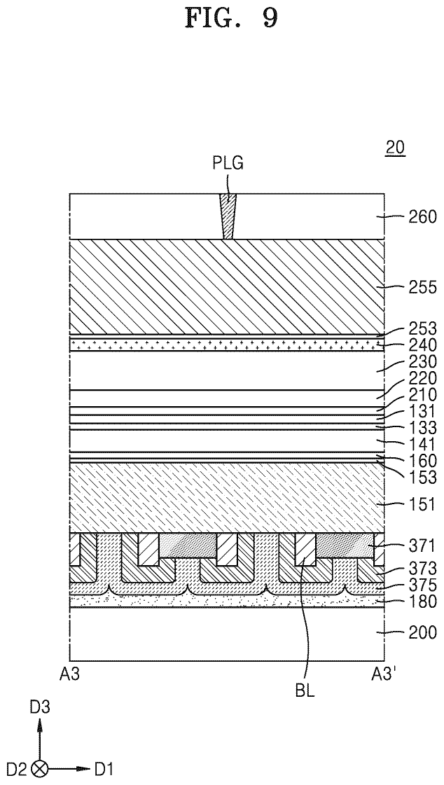

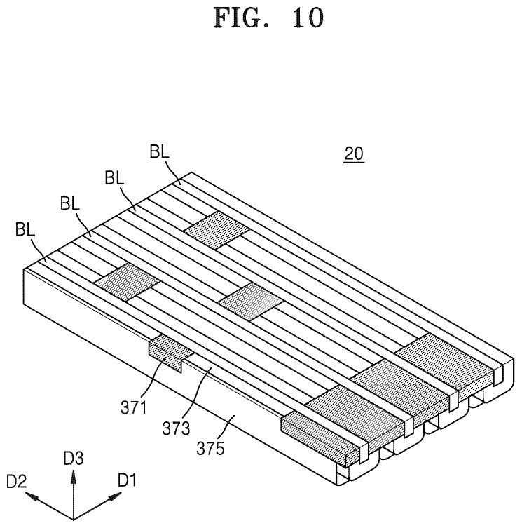

FIG. 6 illustrates a layout of a semiconductor device 20 according to some example embodiments. FIG. 7 is a cross-sectional view taken along line A1-A1′ in FIG. 6. FIG. 8 is a cross-sectional view taken along line A2-A2′ in FIG. 6. FIG. 9 is a cross-sectional view taken along line A3-A3′ in FIG. 6. FIG. 10 is a perspective view illustrating the surroundings of a bit line of the semiconductor device 20 of FIG. 6.

The elements of the semiconductor device 20 and the materials of the elements described below are mostly and substantially the same as or similar to those described above with reference to FIGS. 1 to 5. For convenience of description, therefore, the semiconductor device 20 is described focusing on the differences from the semiconductor device 10.

Referring to FIGS. 6 to 10, the semiconductor device 20 may include memory cells including a VCT.

In the semiconductor device 20 of inventive concepts have, a line shield layer 375 may be between bit lines BL and below the bit lines BL. The line shield layer 375 may reduce coupling noise between bit lines BL adjacent to each other. For example, the line shield layer 375 may correspond to a shielding structure including a conductive material. To insulate the line shield layer 375 that is conductive from the bit lines BL that are conductive, island insulating patterns 371 and line insulating layers 373 may be arranged to fill between the line shield layer 375 and the bit lines BL.

The island insulating patterns 371 may be arranged in zigzag among the bit lines BL in the first direction D1 and the second direction D2. The island insulating patterns 371 may be in contact with respective facing sidewalls of bit lines BL adjacent to each other, and each of the island insulating patterns 371 may be arranged for every three bit lines BL in the first direction D1 along an imaginary line. In some example embodiments, the island insulating patterns 371 may not be arranged in mirror symmetry with respect to the bit lines BL. Each of the island insulating patterns 371 may have a cuboid shape but is not limited thereto. For example, the island insulating patterns 371 may include, but not limited to, a silicon oxide film, a silicon oxynitride film, or a silicon nitride film.

The line insulating layers 373 may be apart from each other in the first direction D1 and may extend in the second direction D2 and cover portions of the island insulating patterns 371 and the bit lines BL from below. The line insulating layers 373 may be respectively in contact with respective facing sidewalls of bit lines BL adjacent to each other and apart from each other in the first direction D1. In some example embodiments, a long space extending in the second direction D2 may be between respective facing sidewalls of line insulating layers 373 adjacent to each other For example, the line insulating layers 373 may include, but not limited to, a silicon oxide film, a silicon oxynitride film, or a silicon nitride film.

The line shield layer 375 may cover the other portions of the island insulating patterns 371 and the line insulating layers 373 from below. The line shield layer 375 may fill the long space between adjacent line insulating layers 373. In some example embodiments, the line shield layer 375 may include a metal material, such as tungsten (W), titanium (Ti), nickel (Ni), or cobalt (Co). In some example embodiments, the line shield layer 375 may include a conductive material, such as graphene, which includes carbon (C).

In the semiconductor device 20 of inventive concepts have, an island insulating pattern 371 may be in a portion of the gap between respective facing sidewalls of adjacent bit lines BL, and line insulating layers 373 and the line shield layer 375 may be in the other portion of the gap between the respective facing sidewalls of the adjacent bit lines BL. In other words, the line shield layer 375 may be in the long space and may include a vertical portion, which faces sidewalls of the bit lines BL, and a horizontal portion, which is on the line insulating layers 373 and faces the bottom surface of the bit lines BL. Here, the vertical portion and the horizontal portion of the line shield layer 375 may form one body.

In some example embodiments, based on the top surface of the substrate 200, the topmost surfaces of the bit lines BL, the topmost surface of the island insulating patterns 371, the topmost surfaces of the line insulating layers 373, and the topmost surface of the line shield layer 375 may be substantially coplanar with one another. Based on the top surface of the substrate 200, the bottommost surfaces of the bit lines BL may be at a lower level than the bottommost surfaces of the island insulating patterns 371 and the bottommost surfaces of the line insulating layers 373 may be at a lower level than the bottommost surfaces of the bit lines BL. Based on the top surface of the substrate 200, the bottommost surface of the line shield layer 375 may be at a lower level than the bottommost surfaces of the line insulating layers 373.

The base insulating layer 180 may be between the substrate 200 and the line shield layer 375. Accordingly, the line shield layer 375 may be surrounded by the base insulating layer 180, the line insulating layers 373, and the island insulating patterns 371.

The semiconductor device 20 of inventive concepts have may efficiently reduce process difficulty by using an engraving method allowing the line shield layer 375 to be formed in a desired region by forming first the island insulating patterns 371 in a portion in which the line shield layer 375 is not to be formed. Accordingly, even when the design rules of semiconductor devices decrease, the line shield layer 375 may be formed to have a desired shape without using an etching process.

Eventually, the semiconductor device 20 of inventive concepts have may enable the decrease of process difficulty and the improvement of electrical characteristics by forming the line shield layer 375, which significantly reduces coupling noise between the bit lines BL and efficiently suppresses the increase of capacitance between the bit lines BL, using an engraving method.

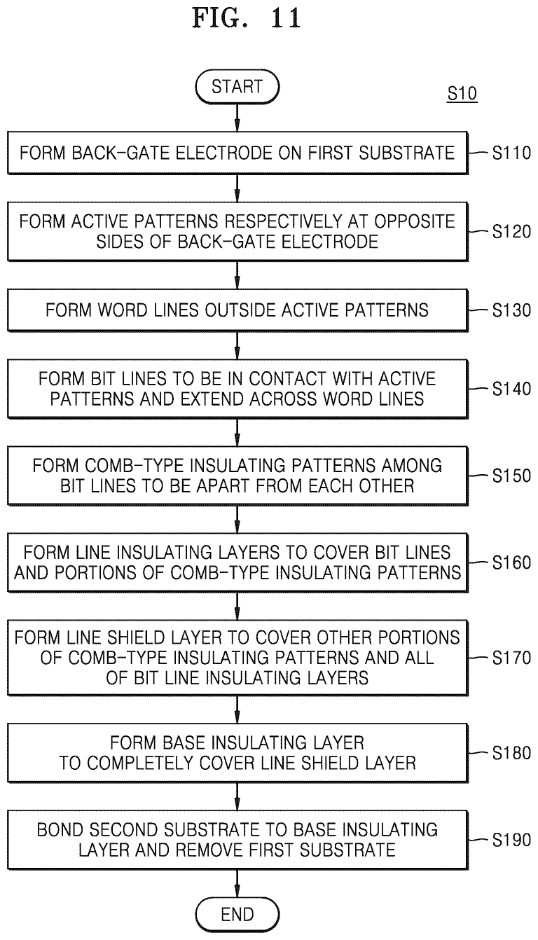

FIG. 11 is a flowchart of a method of manufacturing a semiconductor device, according to various example embodiments.

When it is possible to modify various example embodiments, the order of operations may be different from the order in which the operations are described. For instance, two operations described as being performed sequentially may be substantially performed simultaneously or in a reverse order.

Referring to FIG. 11, a method S10 of manufacturing a semiconductor device may include the sequence of operations S110 to S190.

The method S10 may include forming a back-gate electrode on a first substrate in operation S110, forming active patterns respectively at opposite sides of the back-gate electrode in operation S120, forming word lines outside the active patterns in operation S130, forming bit lines to be in contact with the active patterns and extend across the word lines in operation S140, forming comb-type insulating patterns among the bit lines to be apart from each other in operation S150, forming line insulating layers to cover the bit lines and portions of the comb-type insulating patterns in operation S160, forming a line shield layer to cover the other portions of the comb-type insulating patterns and all of the line insulating layers in operation S170, forming a base insulating layer to completely cover the line shield layer in operation S180, and bonding a second substrate to the base insulating layer and removing the first substrate in operation S190.

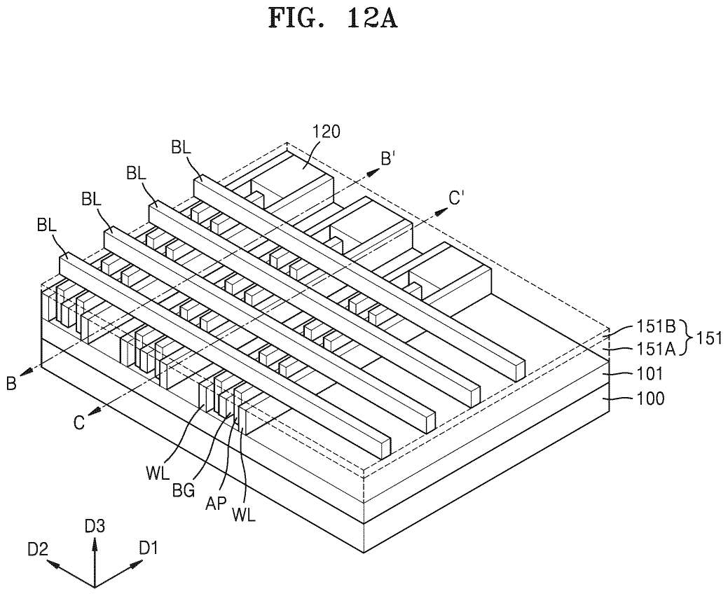

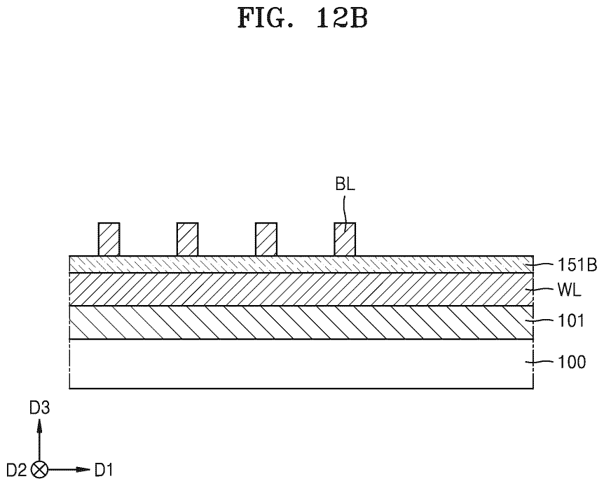

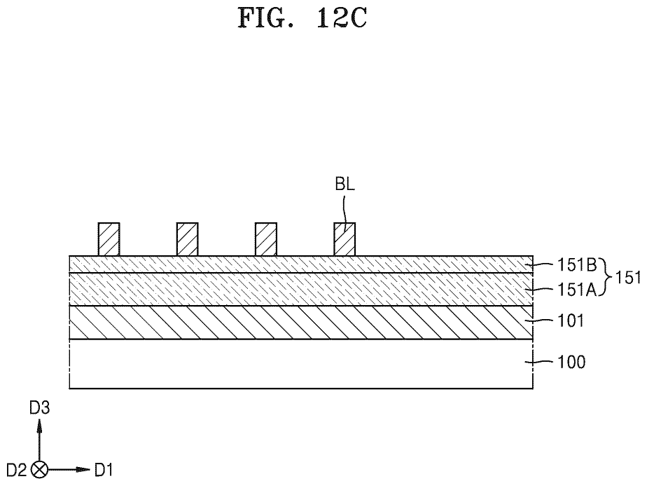

The technical characteristics of operations S110 to S190 are described in detail below with reference to FIGS. 12A to 18C.

FIGS. 12A to 18C are diagrams illustrating the sequential stages in a method of manufacturing a semiconductor device, according to various example embodiments.

In detail, FIGS. 12A, 13A, 14A, 15A, 16A, 17A, and 18A are perspective views of a semiconductor device according to various example embodiments. FIGS. 12B, 13B, 14B, 15B, 16B, 17B, and 18B are cross-sectional views taken along line B-B′ in FIGS. 12A, 13A, 14A, 15A, 16A, 17A, and 18A, respectively. FIGS. 12C, 13C, 14C, 15C, 16C, 17C, and 18C are cross-sectional views taken along line C-C′ in FIGS. 12A, 13A, 14A, 15A, 16A, 17A, and 18A, respectively.

For convenience of understanding, a method of manufacturing the semiconductor device 10 is described focusing on a process of forming the line shield layer 175. A method of forming the other elements of the semiconductor device 10 will be easily understood by one of ordinary skill in the art, based on known techniques, and thus, detailed descriptions thereof are omitted here.

Referring to FIGS. 12A, 12B, and 12C, a first substrate 100 including a buried insulating layer 101 may be prepared.

The first substrate 100 may correspond to a silicon-on-insulator (SOI) substrate. Alternatively, the first substrate 100 may correspond to, for example, a silicon substrate, a germanium substrate, or a silicon-germanium substrate. The first substrate 100 may include a memory cell region.

The buried insulating layer 101 may be on the first substrate 100. For example, the buried insulating layer 101 may include buried oxide. Alternatively, the buried insulating layer 101 may include an insulating film formed by chemical vapor deposition (CVD). For example, the buried insulating layer 101 may include silicon oxide, silicon nitride, silicon oxynitride, and/or a low-k dielectric material.

Subsequently, a first insulating pattern (e.g., 111 in FIG. 2) may be formed. Thereafter, back-gate insulating films (e.g., 113 in FIG. 2) and back-gate electrodes BG may be formed. Back-gate capping patterns (e.g., 115 in FIG. 2) may be formed on the back-gate electrodes BG. A back-gate cutting film 120 may be formed at an end of each of the back-gate electrodes BG.

Subsequently, active patterns AP may be respectively formed at opposite sides of each of the back-gate insulating films (e.g., 113 in FIG. 2). First active patterns (AP1 in FIG. 2) may be on one sidewall of each of the back-gate electrodes BG and apart from each other in the first direction D1. Second active patterns (AP2 in FIG. 2) may be on the opposite sidewall of each back-gate electrode BG and apart from each other in the first direction D1.

Subsequently, gate insulating films (160 in FIG. 2) may be formed to conformally cover the sidewalls of the active patterns AP and the top surfaces of the back-gate capping patterns (115 in FIG. 2). The gate insulating films (160 in FIG. 2) may be formed using one or more of physical vapor deposition (PVD), thermal CVD, low-pressure CVD (LP-CVD), plasma-enhanced CVD (PE-CVD), atomic layer deposition (ALD), etc.

Subsequently, word lines WL may be formed on sidewalls of the active patterns AP. The forming of the word lines WL may include forming a gate conductive film to conformally cover the gate insulating films (160 in FIG. 2) and performing anisotropic etching on the gate conductive film. The shape of the word lines WL may vary with the anisotropic etching, such as dry-etching, of the gate conductive film.

Subsequently, a third insulating pattern 151 may be formed on the remaining portion of the buried insulating layer 101. The third insulating pattern 151 may include a third vertical pattern 151A and a third horizontal pattern 151B.

Subsequently, planarization may be performed on the third insulating pattern 151 to expose the top surfaces of the back-gate capping patterns (115 in FIG. 2). Accordingly, the top surfaces of the active patterns AP may also be exposed.

Subsequently, bit lines BL may be formed on the third horizontal pattern 151B of the third insulating pattern 151 to be in contact with the active patterns AP, wherein the bit lines BL are apart from each other in the first direction D1 and extend in the second direction D2.

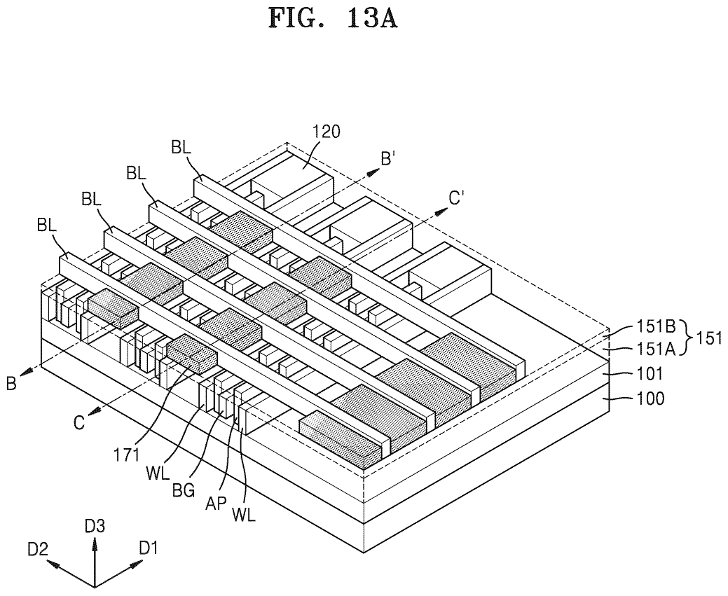

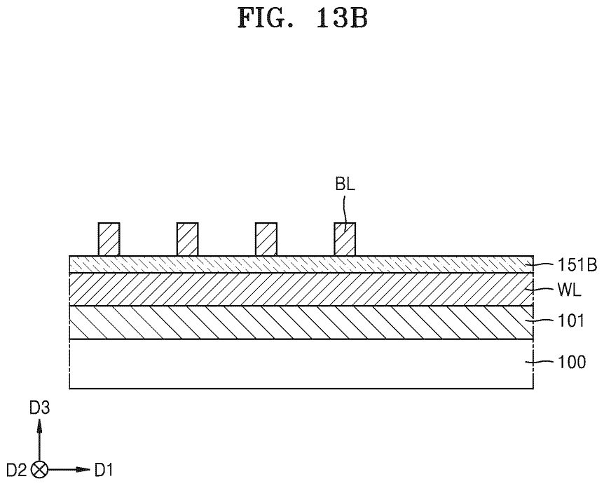

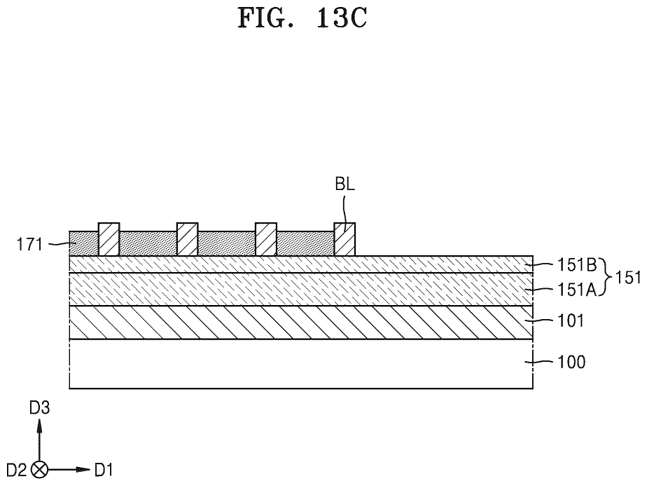

Referring to FIGS. 13A, 13B, and 13C, after the bit lines BL are formed, comb-type insulating patterns 171 may be formed among the bit lines BL.

The comb-type insulating patterns 171 may be formed among the bit lines BL in the first direction D1 and apart from each other in the second direction D2. The comb-type insulating patterns 171 may be formed to be in contact with respective facing sidewalls of bit lines BL adjacent to each other and extend in the first direction D1 along an imaginary line.

In some example embodiments, the comb-type insulating patterns 171 may be formed at opposite sides of each of the bit lines BL in mirror symmetry. Each of the comb-type insulating patterns 171 may have a cuboid shape but is not limited thereto.

In some example embodiments, the level of the top surfaces of the comb-type insulating patterns 171 may be lower than or equal to the level of the top surface of the bit lines BL.

Referring to FIGS. 14A, 14B, and 14C, after the comb-type insulating patterns 171 are formed, line insulating layers 173 may be formed to cover the bit lines BL.

The line insulating layers 173 may be formed to be apart from each other in the first direction D1, extend in the second direction D2, and cover portions of the comb-type insulating patterns 171 and the bit lines BL from above. The line insulating layers 173 may be formed to be respectively in contact with respective facing sidewalls of bit lines BL adjacent to each other and apart from each other in the first direction D1. In some example embodiments, a long space LE extending in the second direction D2 may be formed between respective facing sidewalls of line insulating layers 173 adjacent to each other.

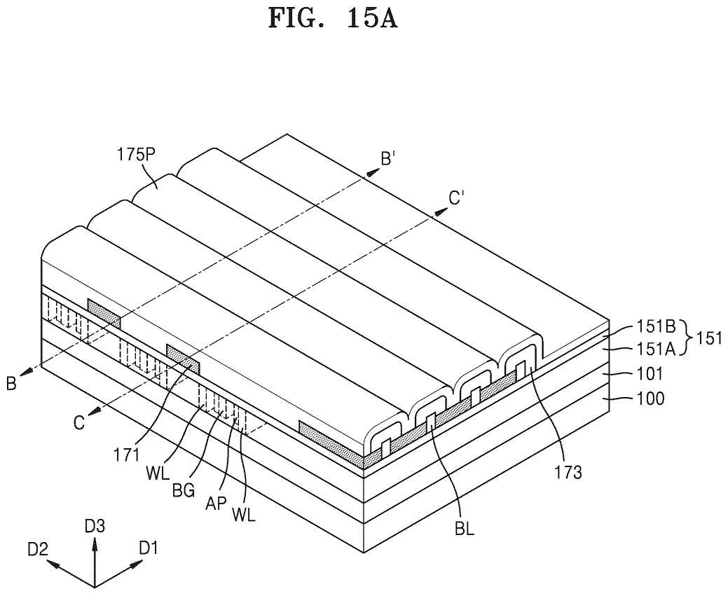

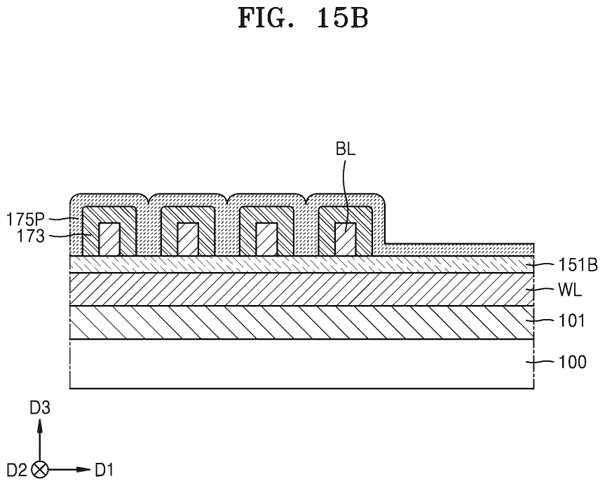

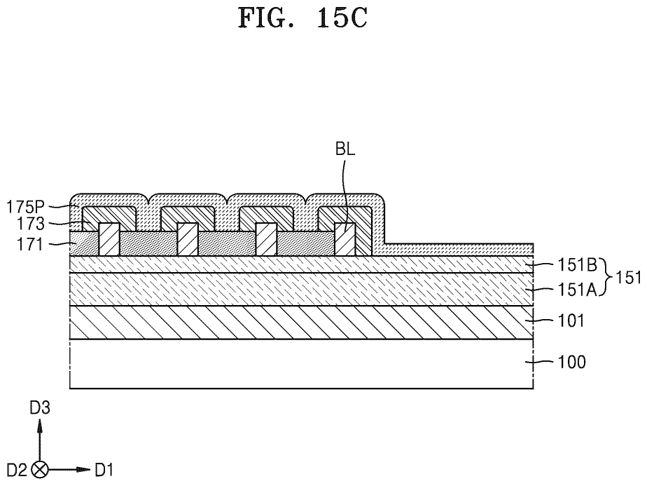

Referring to FIGS. 15A, 15B, and 15C, after the line insulating layers 173 are formed, a preliminary line shield layer 175P may be formed to cover the comb-type insulating patterns 171 and the line insulating layers 173.

The preliminary line shield layer 175P may be formed to cover the other portions of the comb-type insulating patterns 171 and all of the line insulating layers 173 from above. The preliminary line shield layer 175P may be formed to fill the long space LE (in FIG. 14A) between adjacent line insulating layers 173.

A comb-type insulating pattern 171 may be formed in a portion of the gap between respective facing sidewalls of adjacent bit lines BL, and line insulating layers 173 and the preliminary line shield layer 175P may be formed in the other portion of the gap between the respective facing sidewalls of the adjacent bit lines BL.

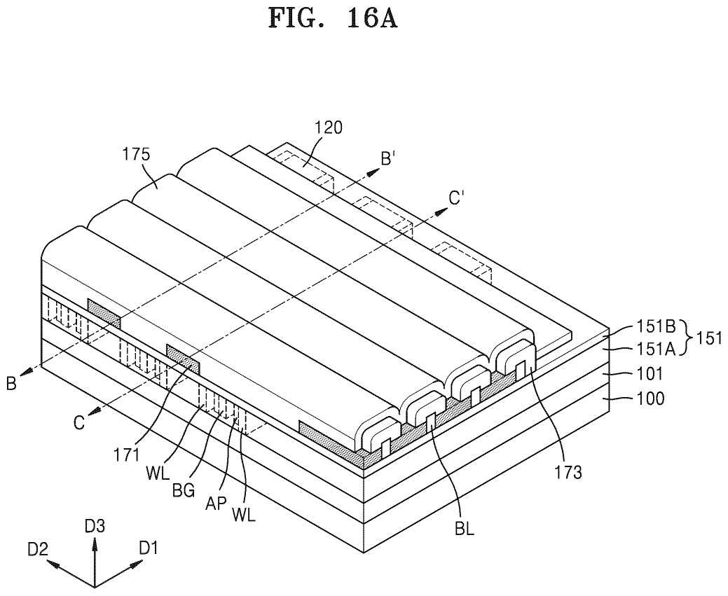

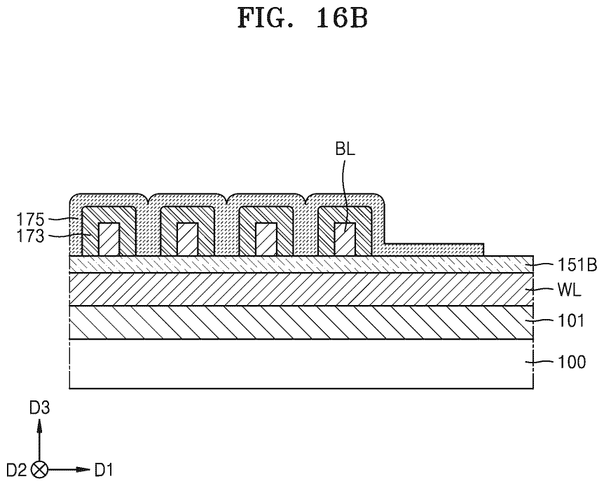

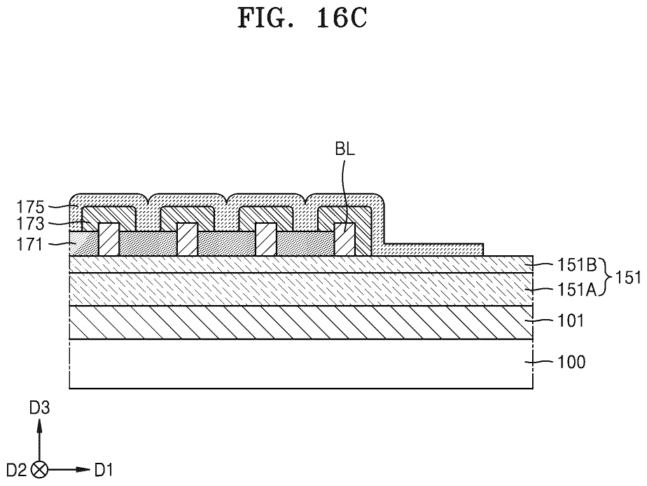

Referring to FIGS. 16A, 16B, and 16C, after the preliminary line shield layer 175P is formed, a line shield layer 175 may be formed by removing an edge of the preliminary line shield layer 175P.

In some example embodiments, an edge of the preliminary line shield layer 175P may be removed to form a contact via (not shown) contacting the word lines WL. The line shield layer 175 may be formed in the long space LE (in FIG. 14A) and may include a vertical portion, which faces sidewalls of the bit lines BL, and a horizontal portion, which is on the line insulating layers 173 and faces the bottom surface of the bit lines BL. Here, the vertical portion and the horizontal portion of the line shield layer 175 may form one body.

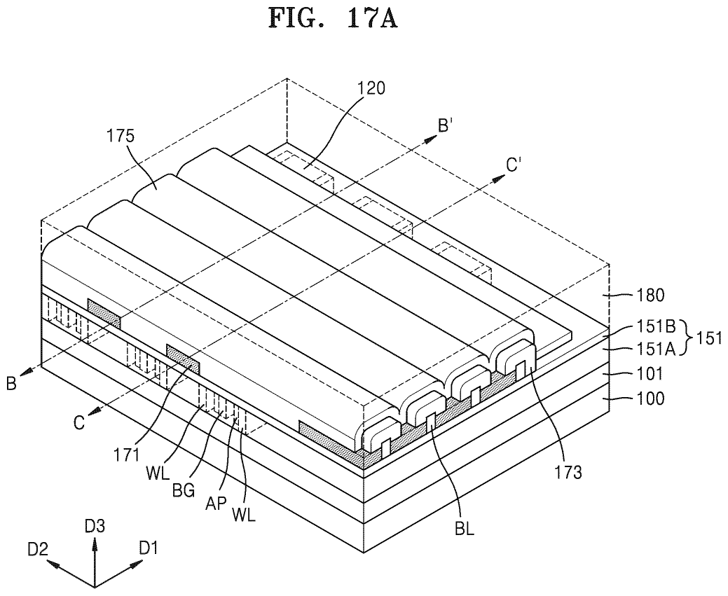

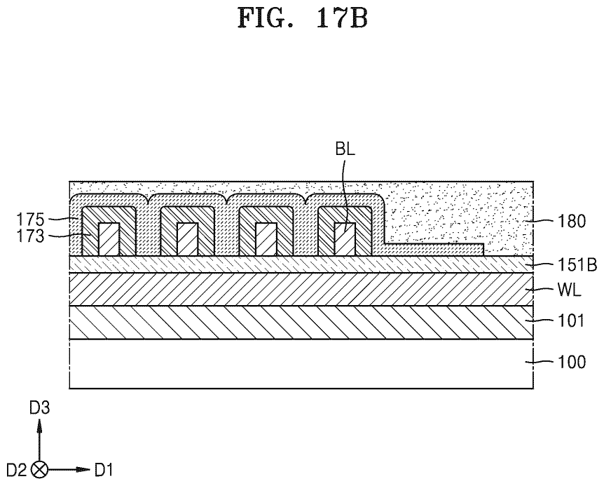

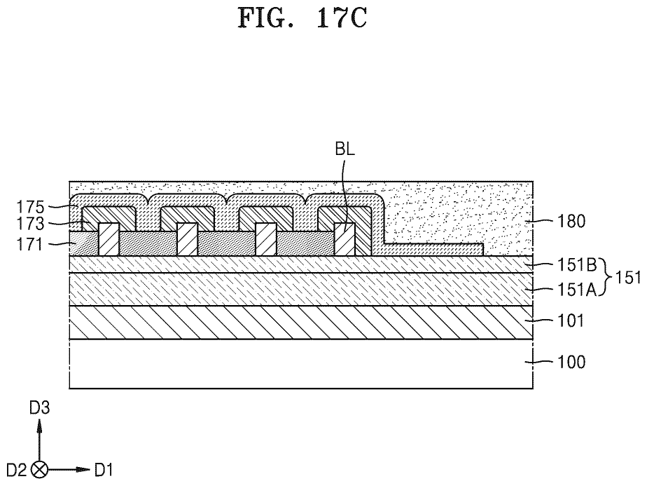

Referring to FIGS. 17A, 17B, and 17C, after the line shield layer 175 is formed, a base insulating layer 180 may be formed to completely cover the line shield layer 175.

Accordingly, the line shield layer 175 may be surrounded by the base insulating layer 180, the line insulating layers 173, and the comb-type insulating patterns 171. For example, the base insulating layer 180 may include, but not limited to, a silicon oxide film, a silicon oxynitride film, or a silicon nitride film.

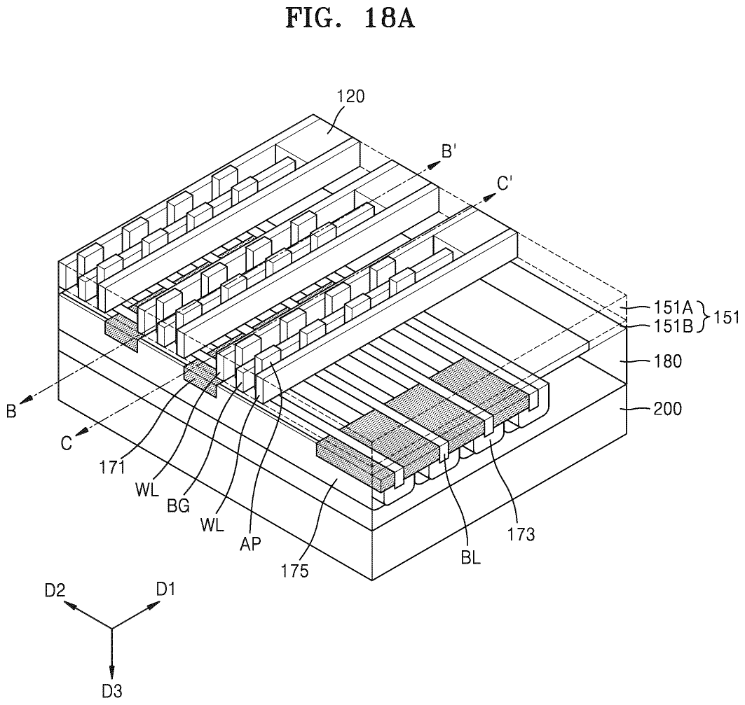

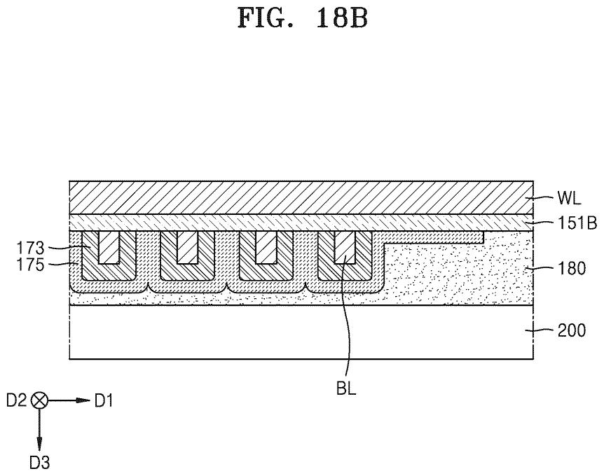

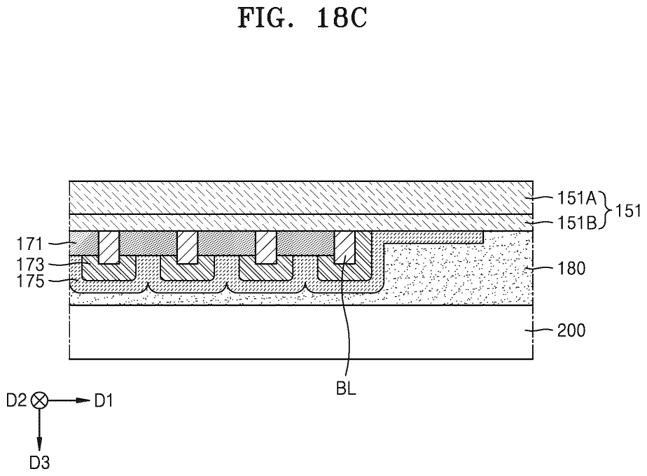

Referring to FIGS. 18A, 18B, and 18C, the first substrate 100 having the base insulating layer 180 thereon may be turned upside down and bonded to the substrate 200.

The substrate 200 may be bonded to the top surface of the base insulating layer 180 by using a bonding interfacial layer (not shown). Here, the substrate 200 may be referred to as a second substrate to be distinguished from the first substrate 100.

For example, the substrate 200 may include monocrystalline silicon, glass, quartz, or the like. For example, the bonding interfacial layer may include silicon carbonitride.

Subsequently, the first substrate 100 and the buried insulating layer 101 may be removed by a backside lapping process. The removing of the first substrate 100 and the buried insulating layer 101 may include exposing the third vertical pattern 151A of the third insulating pattern 151 and the active patterns AP by sequentially performing a grinding process and a wet etching process.

Referring back to FIGS. 1 to 5, contact patterns BC may be formed to respectively cover upper portions of the active patterns AP, and an isolation insulating pattern 230 may be formed to electrically insulate the contact patterns BC from each other. Subsequently, data storage patterns DSP may be formed on the contact patterns BC. In detail, storage electrodes 251 may be respectively formed on the contact patterns BC, and a capacitor dielectric film 253 may be formed to conformally cover the surfaces of the storage electrodes 251. Subsequently, a plate electrode 255 may be formed on the capacitor dielectric film 253. Through the method described above, the semiconductor device 10 may be manufactured.

Eventually, the method of manufacturing the semiconductor device 10 of inventive concepts have may enable the decrease of process difficulty and/or the improvement of electrical characteristics by forming the line shield layer 175, which significantly reduces coupling noise between the bit lines BL and efficiently suppresses or improve the increase of capacitance between the bit lines BL, using an engraving method.

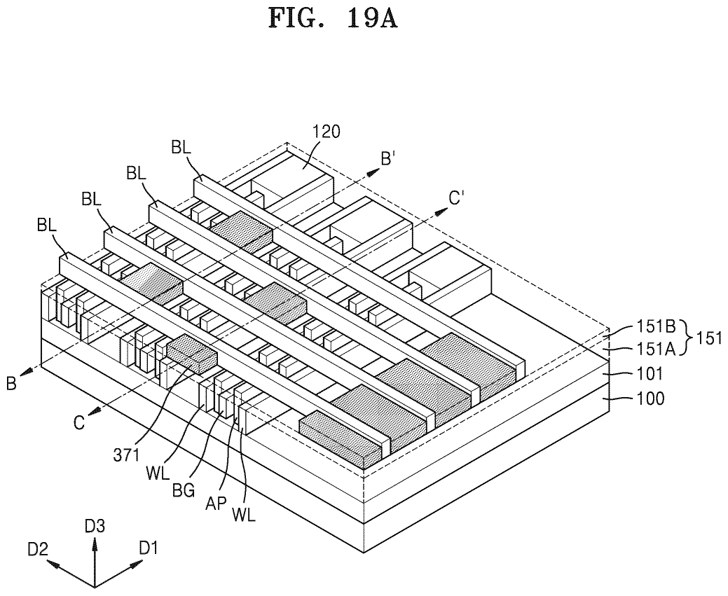

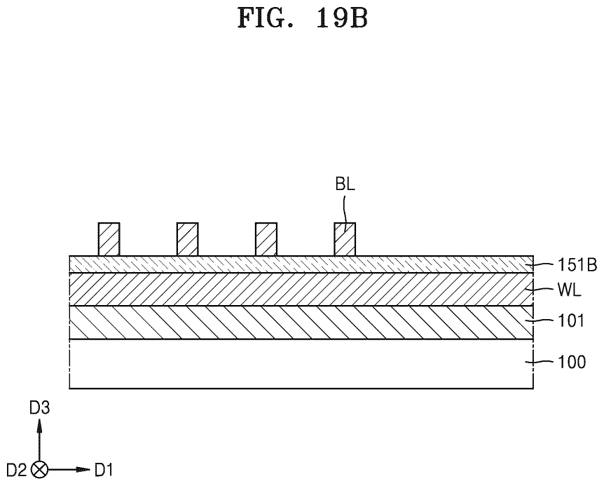

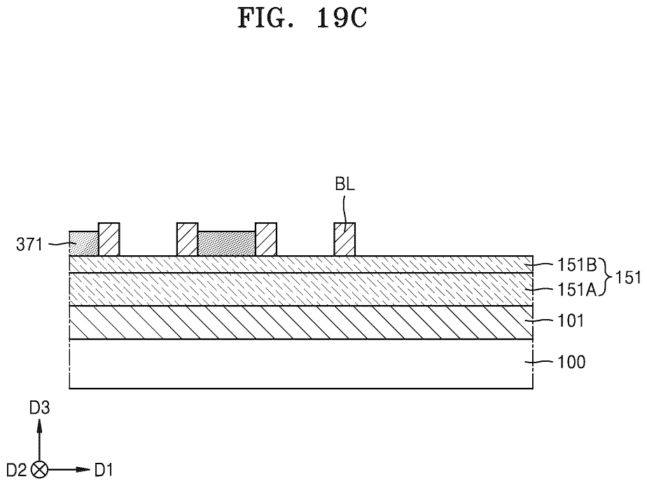

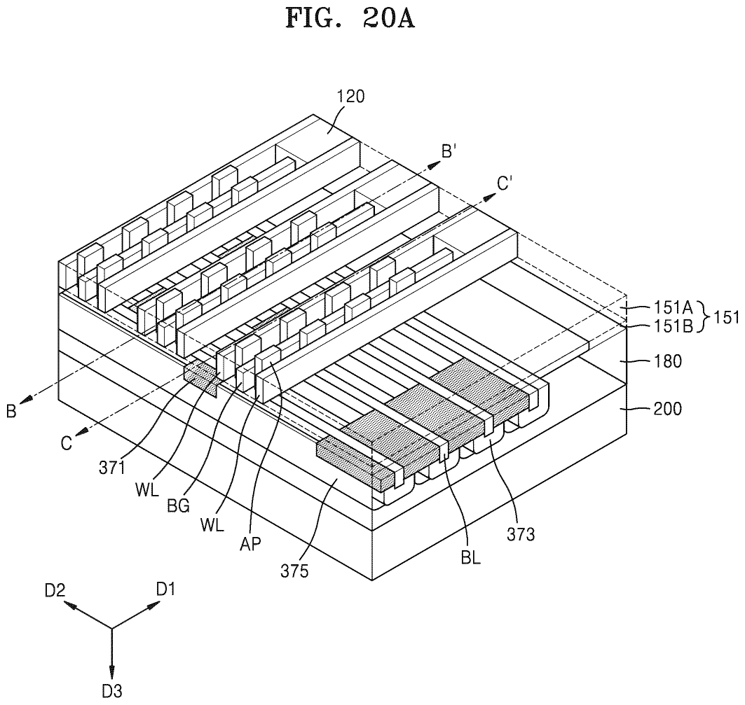

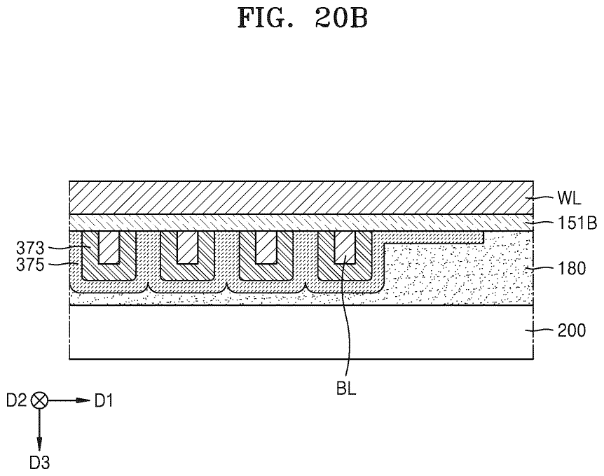

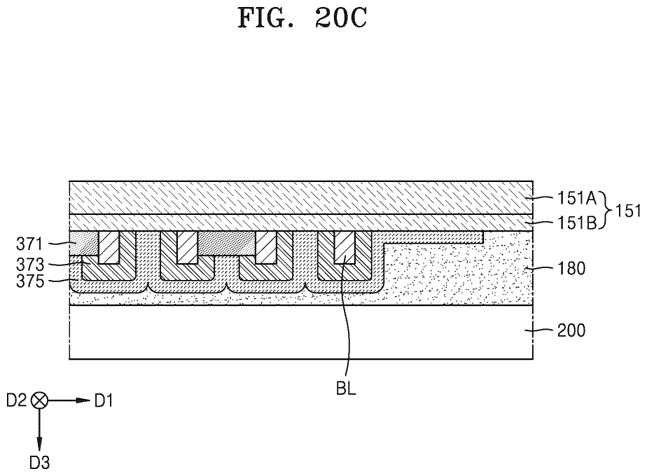

FIGS. 19A to 20C are diagrams illustrating the sequential stages in a method of manufacturing the semiconductor device 20, according to some example embodiments.

In the method of manufacturing the semiconductor device 20, which is described below, the stages of forming most of the elements are substantially the same as or similar to those described above with reference to FIGS. 12A to 18C. Accordingly, for convenience of description, the method of manufacturing the semiconductor device 20 is described below, focusing on the differences from the method of manufacturing the semiconductor device 10.

Referring to FIGS. 19A, 19B, and 19C, after the bit lines BL are formed, island insulating patterns 371 may be formed between the bit lines BL.

The island insulating patterns 371 may be arranged in zigzag among the bit lines BL in the first direction D1 and the second direction D2. The island insulating patterns 371 may be in contact with respective facing sidewalls of bit lines BL adjacent to each other, and each of the island insulating patterns 371 may be arranged for every three bit lines BL in the first direction D1 along an imaginary line. In some example embodiments, the island insulating patterns 371 may not be formed in mirror symmetry with respect to the bit lines BL. Each of the island insulating patterns 371 may have a cuboid shape but is not limited thereto.

Referring to FIGS. 20A, 20B, and 20C, the first substrate 100 having the base insulating layer 180 thereon may be turned upside down and bonded to the substrate 200.

The substrate 200 may be bonded to the top surface of the base insulating layer 180 by using a bonding interfacial layer (not shown). Here, the substrate 200 may be referred to as a second substrate to be distinguished from the first substrate 100.

For example, the substrate 200 may include monocrystalline silicon, glass, quartz, or the like. For example, the bonding interfacial layer may include silicon carbonitride.

Subsequently, the first substrate 100 and the buried insulating layer 101 may be removed by a backside lapping process. The removing of the first substrate 100 and the buried insulating layer 101 may include exposing the third vertical pattern 151A of the third insulating pattern 151 and the active patterns AP by sequentially performing a grinding process and a wet etching process.

Referring back to FIGS. 6 to 10, contact patterns BC may be formed to respectively cover upper portions of the active patterns AP, and an isolation insulating pattern 230 may be formed to electrically insulate the contact patterns BC from each other. Subsequently, data storage patterns DSP may be formed on the contact patterns BC. In detail, storage electrodes 251 may be respectively formed on the contact patterns BC, and a capacitor dielectric film 253 may be formed to conformally cover the surfaces of the storage electrodes 251. Subsequently, a plate electrode 255 may be formed on the capacitor dielectric film 253. Through the method described above, the semiconductor device 20 may be manufactured.

Eventually, the method of manufacturing the semiconductor device 20 of the inventive concept may enable the decrease of process difficulty and the improvement of electrical characteristics by forming the line shield layer 375, which significantly reduces coupling noise between the bit lines BL and efficiently suppresses the increase of capacitance between the bit lines BL, using an engraving method.

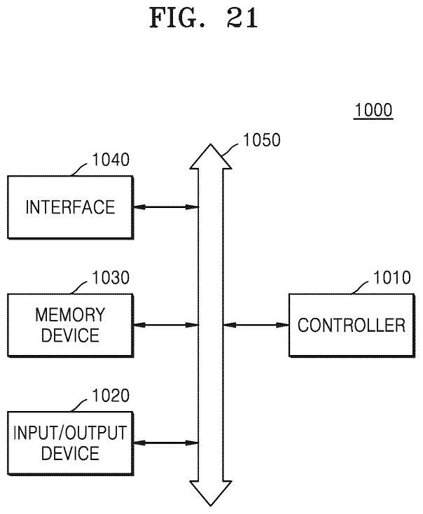

FIG. 21 is a block diagram of a system 1000 including a semiconductor device, according to various example embodiments.

Referring to FIG. 21, the system 1000 may include a controller 1010, an input/output device 1020, a memory device 1030, an interface 1040, and a bus 1050.

The system 1000 may correspond to a mobile system or a system that transmits or receives information. In some example embodiments, the mobile system may include a portable computer, a web tablet, a mobile phone, a digital music player, or a memory card.

The controller 1010 may control an execution program in the system 1000 and include a microprocessor, a digital signal processor, a microcontroller, or the like.

The input/output device 1020 may be used to input data to or output data from the system 1000. The system 1000 may be connected to and may exchange data with an external device, e.g., a personal computer (PC) or a network, through the input/output device 1020. For example, the input/output device 1020 may include a touch screen, a touch pad, a keyboard, or a display.

The memory device 1030 may store data for the operation of the controller 1010 or data processed by the controller 1010. The memory device 1030 may include the semiconductor device 10 or 20 described above according to inventive concepts have.

The interface 1040 may correspond to a data transmission passage between the system 1000 and an external device. The controller 1010, the input/output device 1020, the memory device 1030, and the interface 1040 may communicate with one another through the bus 1050.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, and others.

While inventive concepts have been particularly shown and described with reference to various example embodiments thereof, it will be understood that various changes in form and details may be made therein without departing from the spirit and scope of the following claims. Additionally, example embodiments are not necessarily mutually exclusive with one another. For example, some example embodiments may include one or more features described with reference to one or more figures and may also include one or more other features described with reference to one or more other figures.

What is claimed is:

1. A semiconductor device comprising:
a substrate;
bit lines above a top surface of the substrate, the bit lines apart from each other in a first direction and extending in a second direction crossing the first direction;
comb-type insulating patterns arranged among the bit lines in the first direction and apart from each other in the second direction;
line insulating layers apart from each other in the first direction, extending in the second direction, and covering the bit lines and portions of the comb-type insulating patterns from below;
a line shield layer covering the line insulating layers and remaining portions of the comb-type insulating patterns from below, the line shield layer being conductive;
a pair of active patterns on each of the bit lines;
a back-gate electrode between the pair of active patterns and extending in the first direction; and
a pair of word lines arranged outside the pair of active patterns and extending in the first direction.

2. The semiconductor device of claim 1, wherein
the comb-type insulating patterns extend in the first direction along an imaginary line and are in contact with respective facing sidewalls of the bit lines adjacent to each other.

3. The semiconductor device of claim 2, wherein the comb-type insulating patterns are arranged in mirror symmetry with respect to the bit lines.

4. The semiconductor device of claim 2, wherein the line insulating layers are respectively in contact with the respective facing sidewalls of the bit lines adjacent to each other and are apart from each other in the first direction.

5. The semiconductor device of claim 4, wherein respective facing sidewalls of the insulating layers adjacent to each other define a space, and
wherein the line shield layer fills the space.

6. The semiconductor device of claim 5, wherein,
the comb-type insulating patterns are in a portion of a gap between the respective facing sidewalls of the bit lines adjacent to each other, and
the line insulating layers and the line shield layer are in a remaining portion of the gap between the respective facing sidewalls of the bit lines adjacent to each other.

7. The semiconductor device of claim 6, wherein the line shield layer includes:
a vertical portion in the space; and
a horizontal portion on the line insulating layers, wherein
the vertical portion and the horizontal portion are integral as one body.

8. The semiconductor device of claim 1, wherein,
based on the top surface of the substrate,
topmost surfaces of the bit lines, topmost surfaces of the comb-type insulating patterns, topmost surfaces of the line insulating layers, and a topmost surface of the line shield layer are coplanar with one another.

9. The semiconductor device of claim 8, wherein,
based on the top surface of the substrate,
bottommost surfaces of the bit lines are at a lower level than bottommost surfaces of the comb-type insulating patterns,
bottommost surfaces of the line insulating layers are at a lower level than the bottommost surfaces of the bit lines, and
a bottommost surface of the line shield layer is at a lower level than the bottommost surfaces of the line insulating layers.

10. The semiconductor device of claim 1, further comprising:
a base insulating layer between the substrate and the line shield layer,
wherein the line shield layer is surrounded by the base insulating layer, the line insulating layers, and the comb-type insulating patterns.

11. A semiconductor device comprising:
a substrate;
bit lines above a top surface of the substrate, the bit lines being apart from each other in a first direction and extending in a second direction crossing the first direction;
island insulating patterns zigzagging among the bit lines in the first direction and the second direction;
line insulating layers apart from each other in the first direction, extending in the second direction, and covering the bit lines and portions of the island insulating patterns from below;
a line shield layer covering the line insulating layers and remaining portions of the island insulating patterns from below, the line shield layer being conductive;
a pair of active patterns on each of the bit lines;
a back-gate electrode between the pair of active patterns and extending in the first direction; and
a pair of word lines arranged outside the pair of active patterns and extending in the first direction.

12. The semiconductor device of claim 11, wherein each of the island insulating patterns has a cuboid shape in contact with respective facing sidewalls of the bit lines adjacent to each other.

13. The semiconductor device of claim 12, wherein the island insulating patterns are not arranged in mirror symmetry with respect to the bit lines.

14. The semiconductor device of claim 12, wherein
the island insulating patterns are in a portion of a gap between the respective facing sidewalls of the bit lines adjacent to each other, and
the line insulating layers and the line shield layer are in a remaining portion of the gap between the respective facing sidewalls of the bit lines adjacent to each other.

15. The semiconductor device of claim 11, wherein,
based on the top surface of the substrate,
bottommost surfaces of the bit lines are at a lower level than bottommost surfaces of the island insulating patterns,
bottommost surfaces of the line insulating layers are at a lower level than the bottommost surfaces of the bit lines, and
a bottommost surface of the line shield layer is at a lower level than the bottommost surfaces of the line insulating layers.

16. A method of manufacturing a semiconductor device, the method comprising:
preparing a first substrate including an active layer;
forming a back-gate electrode extending in a first direction in the active layer;
forming a pair of active patterns respectively at opposite sides of the back-gate electrode by patterning the active layer;
forming a pair of word lines outside the pair of active patterns;
forming bit lines extending across the pair of word lines in a second direction crossing the first direction, the bit lines being in contact with first surfaces of the pair of active patterns;
forming comb-type insulating patterns in the first direction among the bit lines, the comb-type insulating patterns being apart from each other in the second direction;
forming line insulating layers covering the bit lines and portions of the comb-type insulating patterns, the line insulating layers being apart from each other in the first direction and extending in the second direction;
forming a line shield layer covering the line insulating layers and remaining portions of the comb-type insulating patterns;
forming a base insulating layer covering the line shield layer;
bonding a second substrate to the base insulating layer;
turning the second substrate upside down; and
removing the first substrate.

17. The method of claim 16, wherein,
in the forming of the comb-type insulating patterns,
the comb-type insulating patterns are in contact with respective facing sidewalls of the bit lines adjacent to each other and extend in the first direction along an imaginary line.

18. The method of claim 17, wherein,
in the forming of the line insulating layers,
the line insulating layers are respectively in contact with the respective facing sidewalls of the bit lines adjacent to each other and are apart from each other in the first direction.

19. The method of claim 18, wherein
the forming of the line shield layer includes:
forming a space extending in the second direction between respective facing sidewalls of the line insulating layers adjacent to each other; and
forming the line shield layer filling the space.

20. The method of claim 19, wherein,
in the forming of the line shield layer,
the line shield layer includes a vertical portion in the space and a horizontal portion on the line insulating layers, and
a bottom surface of the horizontal portion of the line shield layer has a concave-convex structure.

21-25. (canceled)
